(19) United States
(12) Patent Application Publication
(10) Pub. No.: US 2026/0171839 A1
(43) Pub. Date: Jun. 18, 2026

(54) LOAD DISAGGREGATION METHOD AND SYSTEM

(71) Applicant: SAGEMCOM ENERGY & TELECOM SAS, Bois-Colombes (FR)

(72) Inventors: Asma MAALEJ, Bois-Colombes (FR); El Kefi HLEL, Bois-Colombes (FR); Kaveh RAZAZIAN, Bois-Colombes (FR)

(73) Assignee: SAGEMCOM ENERGY & TELECOM SAS, Bois-Colombes (FR)

(21) Appl. No.: 19/409,313

(22) Filed: Dec. 4, 2025

(30) Foreign Application Priority Data
Dec. 18, 2024 (FR) 2414476

(51) Int. Cl. H02J 13/12; G01R 22/06

(52) U.S. Cl. CPC H02J 13/12; G01R 22/063; H02J 13/10; H02J 2105/42; H02J 2105/52

(57) ABSTRACT

Load disaggregation method that comprises an operational phase comprising, in each computing branch i (B-i) among M computing branches executed in parallel and each configured for a type i of electric appliance among M types, with M≥2 and 0<i≤M, implementing: a first classification (401-i) for deciding whether an electric appliance of the type i is present on the electrical network of the home; in the case of a decision that an electric appliance of the type i is present, implementing a second classification for generating an estimated value of an operating state of the electric appliance of the type i, then an estimation of individual power consumption of the electric appliance of the type i. Then concatenating (404), in an output vector, M estimated individual power consumption values associated with the M computing branches.

### TECHNICAL FIELD

The present invention relates to a load disaggregation method and system.

Load disaggregation (also called “load breakdown”) consists in breaking down the power consumption (also called “load”) of a home by detecting the electric appliances (such as solar panels, electric-car chargers, domestic electric appliances, etc) present behind the electricity meter of the home (i.e. present on the electrical network of the home connected to this electricity meter) and determining (estimating) the individual power consumption of each of the electric appliances detected.

### PRIOR ART

The information provided by load disaggregation is essential both for electricity suppliers and for customers (users), since this information can be used to trigger various actions aimed at acting on a future power consumption of at least one of the electric appliances of the home and/or on a future total load, planned and managed by the electricity suppliers.

For example, knowledge of the information provided by the load disaggregation of various homes enables an electricity supplier:
by applying data analysis tools, to predict (estimate) the total load on its electrical network (for example at the national level) and to develop a load shedding and transfer strategy (to flatten out the load curve and to avoid the production limit being exceeded) when the predicted energy consumption exceeds this production limit;
to charge the electric appliances in one and the same home differently. For example, when an electric-vehicle charger is detected, the power consumption thereof is invoiced differently from the other electric appliances in the home, without having recourse to an additional electricity meter for this home;
to change the power-consumption attitude of the users by encouraging them for example to avoid using a few non-essential electric appliances if the production limit has been exceeded. This change in load consumption can be achieved by the electricity suppliers by charging extra for the power consumption of non-essential appliances, which will make it possible to achieve a shift in the load on the national scale and to have a flatter load curve. For example, the suppliers can charge extra for the use of a washing machine at midday during a very hot day and consider a normal price for the power consumed by a refrigerator;
in extreme cases, to implement load shedding in homes not responding to the call to reduce load during times of high demand. The electricity supplier may also implement selective load shedding in a home, relating solely to electric appliances detected as being high energy consuming, if the functionality of remote activation and deactivation of the electric appliances is available and has been accepted in advance by the user;
etc.

On the user side, knowledge of the information provided by load disaggregation enables this user, via a display on a device (for example a smartphone, tablet or a dedicated device):
to detect high energy consuming electric appliances;
to estimate their consumption and invoicing, in particular with a view to changing their consumption attitude (for example, knowing the power consumption of each appliance active on the electrical network of their home enables the user to detect the appliance most consuming power and to shift the time of use thereof to periods where the kWh price is the least expensive);
to estimate any variation in power consumption of the electric appliances, in order to detect excessive consumption of the appliances used;
etc.

One current known solution for load disaggregation uses a detection of the energy footprint based on a hidden Markov model (HMM). This current known solution is advantageous since it is a technique for non-intrusive load monitoring (NILM), which benefits from a high level of acceptance by the users and low implementation costs compared with the prior known load-disaggregation solutions, which were invasive. However, the current known load-disaggregation solution is not entirely satisfactory since it has several drawbacks. Firstly, HMM has a limitation in estimating the power of appliances with several operating states. Secondly, its ability to model dependencies between sequential data (reflecting the habits of use of appliances for example) is limited. This is because HMM is based solely on the prior state for being able to estimate the load at time t. In addition, the computational complexity increases exponentially with the number of electric appliances to be considered by load disaggregation.

There is therefore a need to provide a novel load-disaggregation solution that does not have the aforementioned drawbacks of the current known solution.

### DISCLOSURE OF THE INVENTION

A load disaggregation method is proposed, implemented by a load disaggregation system comprising electronic circuitry, the method comprising an operational phase comprising:
in each computing branch i among M computing branches executed in parallel and each configured for a type i of electric appliance among M types, with M≥2 and 0<i≤M, implementing
   a first classification comprising:
      obtaining first measurements of a power consumption of a home, provided during a first interval of time by a smart electricity meter located at the input of an electrical network of the home;
      injecting the first measurements into a first machine learning model of the deep neural network type, configured to provide, during the first interval of time, according to the first measurements, first successive estimated values of an operating state of an electrical appliance of the type i; and
      deciding, according to the first successive estimated values, whether an electric appliance of the type i is present on the electricity network of the home;
   if the first classification results in a decision that an electric appliance of the type i is present on the electricity network of the home;
      a second classification comprising:
         obtaining N second measurements of the power consumption of the home, provided during a second interval of time, subsequent to the first interval of time, by the smart electricity meter, with N>2;
         injecting the N second measurements into a second machine learning model of the deep neural network type, configured to provide, according to the N second measurements, a second estimated value of an operating state of an electrical appliance of the type i;
      an estimation of individual power consumption of the electric appliance of the type i, comprising: injecting the N second measurements of the power consumption of the home and the second estimated value of the operating state of the electric appliance of the type i, into a third machine learning model of the deep neural network type, configured to provide an estimated value of the individual power consumption of the electric appliance of the type i, according to the N second measurements and the second estimated value of the operating state of the electrical appliance of the type i; and
concatenating, in an output vector, M estimated values of individual power consumption associated with the M computing branches, an estimated value of individual power consumption associated with a computing branch i being equal to zero consumption, respectively with the estimated value provided by the third machine learning model of the computing branch i, when the first classification of the computing branch i delivers a decision on absence and respectively a decision on presence of an electric appliance of the type i.

Thus, by virtue of its parallel architecture, comprising M computing branches that are executed in parallel, the solution proposed makes it possible to simultaneously detect the presence of several electric appliances (up to M electric appliances each of a distinct type) and to estimate the individual power consumption of each. The computations are reduced because, in each computing branch, the operations that follow the first classification are performed only if the result of this first classification is that an electric appliance (of the type treated by the branch concerned) is detected as being present. Furthermore, these operations can be different from one branch to another, which makes it possible to best adapt in each branch to the type of electric appliance that is being treated therein.

According to a particular embodiment, the injection of the first measurements into the first machine learning model comprises K iterations, with K>2, of an injection of N′ first measurements into the first machine learning model, configured to provide, according to the N′ first measurements, a first estimated value of an operating state of an electric appliance of the type i; and the decision relating to the presence of an electric appliance of the type i on the electrical network of the home is dependent on the K first successive estimated values resulting from the K iterations.

According to a particular embodiment, in each computing branch i, the first classification is repeated periodically, with a predetermined period between two iterations.

According to a particular embodiment, in each computing branch i, at least two iterations of the second classification, of the estimation of individual power consumption of the electric appliance of the type i and of the concatenation are implemented, a new iteration being implemented when a new second measurement is provided by the smart electricity meter, the N second measurements obtained during the new iteration comprising the new second measurement and N-1 second measurements that precede the new second measurement.

According to a particular embodiment, for at least one of the computing branches, the third machine learning model of the deep neural network type is a variational autoencoder model comprising an encoder using a first recurrent neural network and a decoder using a second recurrent neural network.

According to a particular embodiment, the operational phase comprises: transmitting the output vector to at least one item of equipment belonging to the group comprising an item of equipment used by a member of the home and an item of equipment of an electricity supplier supplying the home, with a view to triggering at least one action aimed at acting on a future power consumption of at least one of the electric appliances of the home or on a future total load, planned and managed by the electricity supplier and including a future power consumption of the home.

According to a particular embodiment, said at least one action belongs to the group comprising:
a display of the operating states and of the individual power consumption of each electric appliance in the home;
a construction of a history of operation of each electric appliance in the home;
a prediction of a future power consumption of the home;
a detection of a deficiency of one of the electric appliances in the home;
a shifting of the future total load, planned and managed by the electricity supplier; and
a partial shedding of the future total load, planned and managed by the electricity supplier.

According to a particular embodiment, in each computing branch i, estimating the individual power consumption of the electric appliance of the type i comprises:
applying an adaptive filter to the N second measurements of the power consumption of the home, to obtain N second filtered measurements; and
injecting the N second filtered measurements and the second estimated value of the operating state of the electric appliance of the type i, into the third machine learning model of the deep neural network type, configured to provide the estimated value of the individual power consumption of the electric appliance of the type i, according to the N second filtered measurements and the second estimated value (i.e. the result of the second classification).

According to a particular embodiment, the method comprises an adjustment phase comprising, for the adaptive filter of a computing branch i, after a learning phase of the third machine learning model of the computing branch i and before the operational phase using the adaptive filter of the computing branch i:
using the third machine learning model of the computing branch i, with at least one learning data item filtered by the adaptive filter and associated with an output label, to obtain an estimated value of the individual power consumption of the electric appliance of the type i, referred to as the estimated consumption value;
comparing the estimated consumption value with the output label; and
adjusting coefficients of the adaptive filter according to a result of the comparison between the estimated consumption value and the output label.

According to a particular embodiment, the method comprises a learning phase comprising, for a learning of the third machine learning model of at least one of the computing branches:
generating non-real learning data with a generative adversarial network model, comprising a generator using a first recurrent neural network and a discriminator using a second recurrent neural network;
constructing an augmented set of learning data, by adding the non-real learning data to real learning data collected; and
implementing a learning of the third machine learning model with the augmented set of learning data.

According to a particular embodiment, the method comprises an updating phase comprising, for updating the third machine learning model of at least one of the computing branches:
identifying a closest model, from a plurality of reference models, by making a correlation between on the one hand the estimated value provided by the third machine learning model during the operational phase and on the other hand the estimated values provided by the plurality of reference models after injection of data identical to data injected into the third machine learning model during the operational phase; and
implementing a new learning of the third machine learning model, with a new set of learning data previously generated with the closest model.

A computer program product is also proposed, comprising instructions causing the execution, by a processor, of the load disaggregation method mentioned above according to any one of the embodiments thereof, when said instructions are executed by the processor.

A storage medium is also proposed, storing such instructions.

A load disaggregation system is also proposed, comprising electronic circuitry configured to implement the load disaggregation method mentioned above according to any one of the embodiments thereof.

A smart electricity meter is also proposed, comprising the load disaggregation system mentioned above.

### BRIEF DESCRIPTION OF THE DRAWINGS

The features of the invention mentioned above, as well as others, will emerge more clearly from the reading of the following description of at least one example embodiment, said description being made in relation to the accompanying drawings, among which:

FIG. 1 illustrates schematically a smart electricity meter configured to implement a load disaggregation method according to an embodiment of the invention;

FIG. 2 illustrates schematically an example of hardware architecture of the smart electricity meter of FIG. 1;

FIG. 3 illustrates schematically a variant wherein the load disaggregation method is implemented in cloud computing;

FIG. 4 illustrates schematically a first representation of an operational phase of the load disaggregation method, in one embodiment;

FIG. 5 illustrates schematically a second representation of the operational phase of the load disaggregation method, which makes clear and completes the first representation of FIG. 4;

FIG. 6 illustrates schematically an example of an algorithm for iterating the first classification appearing in FIG. 4;

FIG. 7 illustrates schematically a particular implementation of the model for estimating individual power consumption appearing in FIG. 5;

FIG. 8 illustrates schematically a representation of a phase of adjustment of the coefficients of each adaptive filter appearing in FIG. 5;

FIG. 9 illustrates schematically a representation of a learning phase of each model for estimating individual power consumption appearing in FIG. 5;

FIG. 10 illustrates schematically a particular implementation of the step of generating non-real learning data, appearing in FIG. 9; and

FIG. 11 illustrates schematically a representation of a phase of updating each model for estimating individual power consumption appearing in FIG. 5.

### DETAILED DISCLOSURE OF EMBODIMENTS

### Summary

The present invention defines a solution for load disaggregation. It relates to an artificial intelligence solution that can be implemented in a smart electricity meter (an implementation in edge computing is then spoken of). In a variant, the solution proposed can also be implemented in cloud computing. Whatever the implementation, the solution proposed makes it possible firstly to autodetect, behind the smart electricity meter, electric appliances present (such as solar panels, electric-car chargers, domestic electrical appliances, etc) and secondly to estimate the power consumption of each electric appliance detected. In a particular embodiment, it comprises a plurality of operating phases: a learning phase (also called “training phase”) for models used during the operational phase, a phase of adjusting coefficients of adaptive filters used in the operational phase to minimise the power-measurement noises, an operational phase (also called “functional phase”) and a phase of updating models for estimating individual power consumption.

The learning phase consists in preparing the artificial intelligence solutions (i.e. the various machine learning models) next used during the operational phase. In a particular embodiment, apart from the conventional learning operations, the learning phase proposes the use of the augmentation of data in order to improve the precision of the estimation of the power consumption or to reduce the time taken for recording the learning data necessary for constructing a reliable training dataset.

The operational phase makes it possible to detect the operating state of the electrical appliances and to estimate the individual power consumptions thereof. In a particular embodiment, this phase relies on an architecture comprising M computing branches that are executed in parallel, each branch being dedicated to a type of appliance and using:
a double classification comprising a first classification in order to detect the presence of an electric appliance of the type concerned behind the electricity meter, and a second classification in order to detect the operating events of an appliance of the type concerned if such has been detected;
a specific model for estimating individual power consumption, for load disaggregation;
the activation or deactivation of the remainder of the branch (i.e. the second classification and the specific model for estimating individual power consumption) according to the result of the autodetection provided by the first classification; and
an adaptive filter for reinforcing the estimation provided by the model for estimating individual power consumption.

The updating phase implements, for each of the aforementioned computing branches, an updating of the model for estimating individual power consumption, with the objective of improving the estimation provided.

These Various Phases Are Presented In More Detail Below.

In a particular embodiment, the solution proposed applies to electric appliances of type I and type II. An electric appliance of type I is an appliance the only possible operating states of which are “ON” and “OFF”. An example of an electric appliance of type I is the electric lamp. An electric appliance of type II is an appliance the operation of which is governed by a state machine and therefore has various operating states (including at least one operating state other than “ON” and “OFF”). An example of an electric appliance of type II is the washing machine.

### Case Where the Load Disaggregation Method is Implemented in the Electricity Meter

In a first implementation, the load disaggregation solution proposed is implemented in a smart electricity meter, i.e. in edge computing.

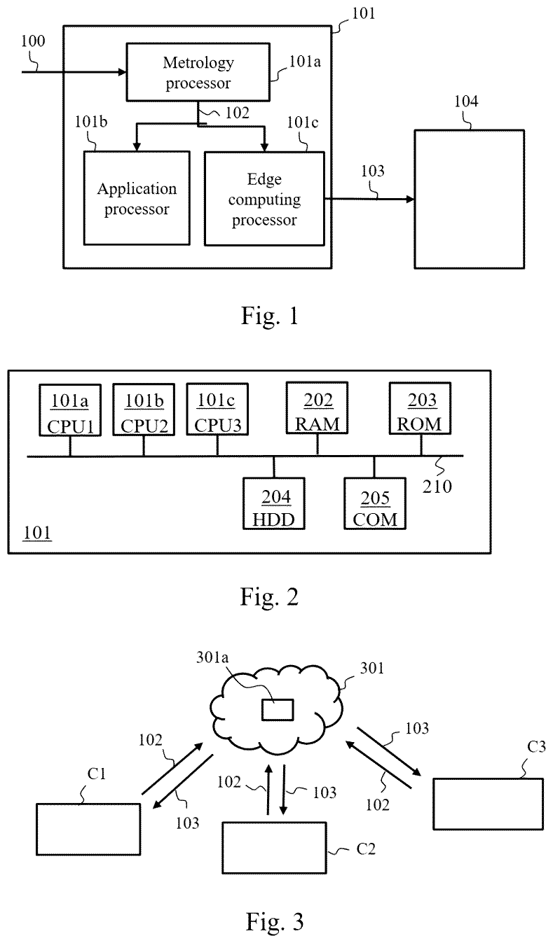

In the example in FIG. 1, the smart electricity meter 101 comprises three processors cooperating with each other:
a metrology processor 101a, making it possible to sample the analogue input signal 100 in order to provide samples (in particular successive measurements 102, for example each second, of the power consumption of the home) to the other two processors, namely an application processor 101b and an edge computing processor 101c;
the role of the application processor 101b is to compute the various energy footprints of the home. It also makes it possible to integrate an application protocol for the smart metering applications (for example: DLMS/COSEM, IEEE1377/ANSI C12.19, CLC/FprTS 50568-5, etc); and
the edge computing processor 101c is dedicated to processing artificial intelligence solutions and metrology applications.

More precisely, the edge computing processor 101c implements the load disaggregation solution proposed that makes it possible, according to the successive measurements 102 of the power consumption of the home, to provide (for example each second) load disaggregation information 103 (information comprising the list of appliances detected and, for each of these, the individual power consumption). The edge computing processor 101c transmits this information 103 to local equipment 104 (for example display equipment) or to remote equipment (for example a storage and processing server located in cloud computing), through a communication protocol. This communication protocol is for example Wi-Fi for home networks or HAN (standing for “home area network”) and Wi-SUN for field area networks (FAN).

The electricity meter 101, the architecture of which is shown by FIG. 1, makes it possible to perfectly interact in a smart grid context, where the edge computing processor 101c is the core for providing multple solutions combining both the Internet of Things (IoT) and artificial intelligence. This enables it to interact with various sensors or various data centres of the electricity suppliers.

FIG. 2 illustrates schematically an example of hardware architecture of the smart electricity meter 101 of FIG. 1, which then comprises, connected by a communication bus 210: the aforementioned three processors (metrology processor 101a, application processor 101b and edge computing processor 101c, also denoted CPU1, CPU2 et CPU3); a random access memory RAM 202; a read-only memory ROM 203, for example a flash memory; a data storage device, such as a hard disk drive HDD, or a storage medium reader, such as an SD (“Secure Digital”) card reader 204; and at least one communication interface 205 enabling the meter 101 to interact in particular with the local equipment 104 or remote equipment in cloud computing.

The read-only memory ROM 203 stores the software (instructions) executed by the various processors 101a, 101b and 101c. It is also used to store the various artificial-intelligence models (machine learning models) relating to load disaggregation, as well as any other software using the smart electrical networks that require processing at the electricity meter. In particular, the edge computing processor 100c is capable of executing instructions loaded in the RAM 202 from the ROM 203, from an external memory (not shown), from a storage medium such as an SD card, or from a communication network (not shown). When the meter 101 is powered up, the edge computing processor 100 c is capable of reading instructions from the RAM 202 and executing them. These instructions form a computer program causing the implementation, by the processor 100c, of the behaviours, steps and algorithm described here (load disaggregation method).

All or some of the behaviours, steps and algorithm described here can thus be implemented in software form by executing a set of instructions by a programmable machine, such as a DSP (“digital signal processor”) or a microcontroller, or be implemented in hardware form by a machine or a dedicated component (“chip”) or a dedicated set of components (“chipset”), such as an FPGA (“field-programmable gate array”) or an ASIC (“application-specific integrated circuit”). In general terms, the meter 101 comprises electronic circuitry arranged and configured to implement the behaviours, steps and algorithms described here.

### Case Where the Load Disaggregation Method is Implemented in Cloud Computing

FIG. 3 illustrates schematically a variant wherein the load disaggregation method is implemented in cloud computing 301, for example in a remote server 301a.

In this case, each of the smart electricity meters (referenced C1, C2 and C3 in FIG. 3) transmits its successive measurements 102 of power consumption of the home to the remote server 301a. This transmission can be done at a predetermined frequency (for example each 5 minutes, each 15 minutes or each hour). In return, the remote server 301a transmits, to each of the meters, the result of the implementation of the load disaggregation method for the meter concerned (i.e. the load disaggregation information 103 for this meter).

### Operational Phase

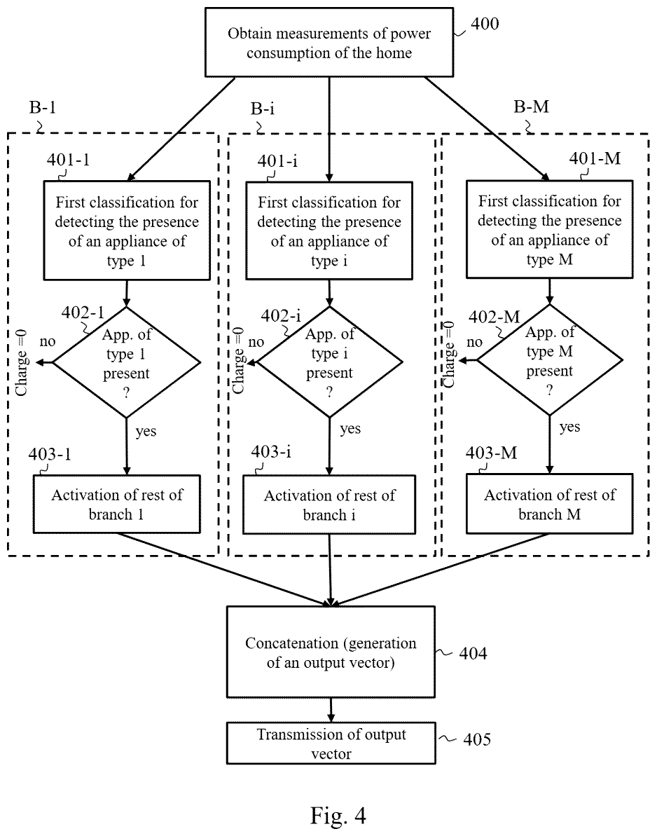

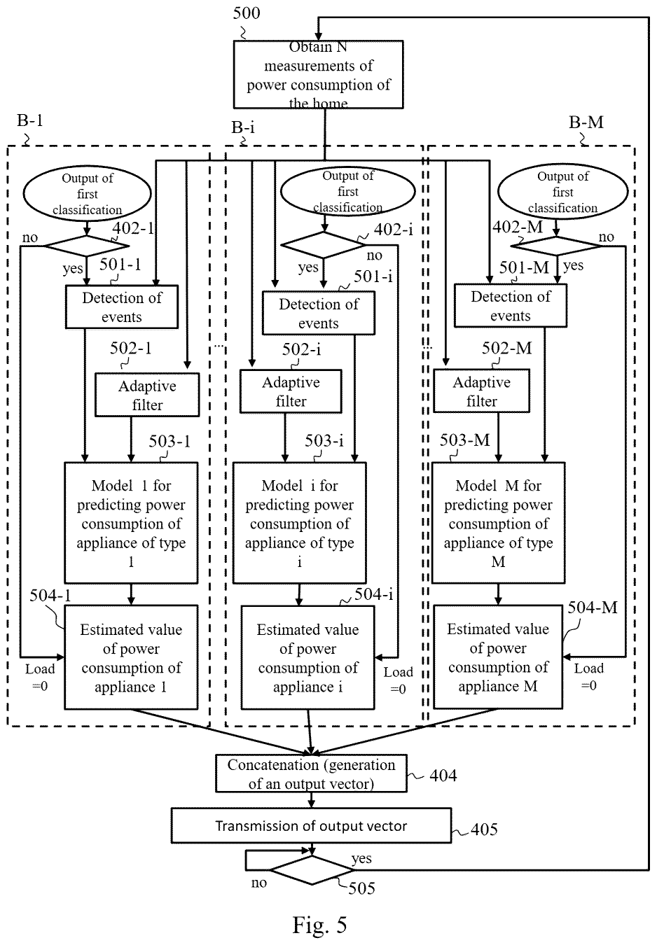

The implementation of the global load disaggregation solution is illustrated in FIGS. 4 and 5. The solution provides a load disaggregation, in parallel, for a plurality of electric appliances in the same home, using an architecture in the form of parallel computing branches. The load disaggregation solution uses as input the power consumption of the home, and generates as output a result in the form of a vector presenting the estimation of the individual power consumption of a set of electric appliances.

More precisely, FIG. 4 illustrates schematically a first representation of the operational phase of the load disaggregation method, in one embodiment. By way of example, the case is adopted, in the remainder of the description, of the first implementation illustrated in FIGS. 1 and 2, where the method is implemented by the processor 101c (edge computing processor). The operational phase comprises M computing branches (referenced B-1 to B-M) which are executed in parallel, with M≥2 (i.e. M is a non-zero positive integer). Each computing branch i, with 0<i≤M, is configured for a type of electric appliance among M types. For example, M=30.

In each computing branch i, the processor 101c first of all implements a first classification in which:
in a step 400 (common to the M computing branches), the processor 101c obtains first measurements (referenced 102 in FIG. 1) of the power consumption of the home, provided during a first interval of time (for example of the order of a few minutes to a few days) by the metrology processor 101a;
in a step 401-i (specific to the computing branch i), the processor 101c injects the first measurements into a first machine learning model of the deep neural network type, configured to provide, during the first interval of time, according to the first measurements, first successive estimated values of an operating state of an electrical appliance of the type i. In other words, the first model is pre-trained for the type of appliance in question in the computing branch i); and
in a step 402-i (specific to the computing branch i), the processor 101c decides, according to the first successive estimated values (for example according to the duration and continuity of operating states “ON” detected), whether an electric appliance of the type i is present on the electricity network of the home.

Thus, at the end of the execution of the first classification in each of the M computing branches, the processor 101c has, for each branch i, presence information indicating whether an electric appliance of the type i is present or absent. The list of electric appliances detected as present constitutes a first part of the load disaggregation information. For the record, the second part of the load disaggregation information is the estimation of the individual power consumption of each of the electric appliances detected as present.

In each computing branch i, if the decision taken at the step 402-i is that an electric appliance of the type i is present, the processor 101c performs the operation referenced 403-i consisting in activating the rest of the computing branch B-i (i.e. as detailed below in relation to FIG. 5, a second classification and an estimation of individual power consumption) in order to obtain an estimated value of the individual power consumption of the electric appliance of type i. On the other hand, if the decision taken at the step 402-i is that an electric appliance of the type i is not present, the processor 101c does not activate the rest of the computing branch B-i and considers directly that the individual power consumption of the electric appliance of type i is zero.

In a step 404, the processor 101c concatenates, in an output vector, the M estimated values of individual power consumption associated with the M computing branches. As explained above, each estimated value is either the one estimated by the rest of the branch if the latter has been activated (operation 403-i), or zero if the rest of the branch has not been activated (response “no” to the test 402-i). Thus the output vector contains the two parts of the load disaggregation information 103: the list of the appliances detected contains the electric appliances for which the individual power consumption is zero, and the individual power consumption of the electric appliances detected is given by the non-zero values of the output vector.

In a step 405, processor 101c transmits the output vector to the local equipment 104 or to the remote equipment (for example the storage and processing server located in cloud computing).

Estimating the individual power consumption of each electric appliance makes it possible to construct its operating history. This history can be used in order to store the habits of the user, which will assist the electricity supplier in better predicting the power consumption on its national network for example. In addition, this history makes it possible to detect wear on the appliance in question and a change in its electrical signature. Thus this makes it possible to indicate to the user whether the appliances detected as present on the network of the home are deficient and are for example beginning to consume more power.

More generally, the processor 101c transmits the output vector to at least one item of equipment belonging to the group comprising an item of equipment used by a member of the home and an item of equipment of an electricity supplier supplying the home, with a view to triggering at least one action aimed at acting on a future power consumption of at least one of the electric appliances of the home or on a future total load, planned and managed by the electricity supplier and including a future power consumption of the home. A list (non-exhaustive) of actions comprises for example, a display of the operating states and of the individual power consumption of each electric appliance in the home; a construction of a history of operation of each electric appliance in the home; a prediction of a future power consumption of the home; a detection of a deficiency of one of the electric appliances in the home; a shifting of the future total load, planned and managed by the electricity supplier; a partial shedding of the future total load, planned and managed by the electricity supplier; etc.

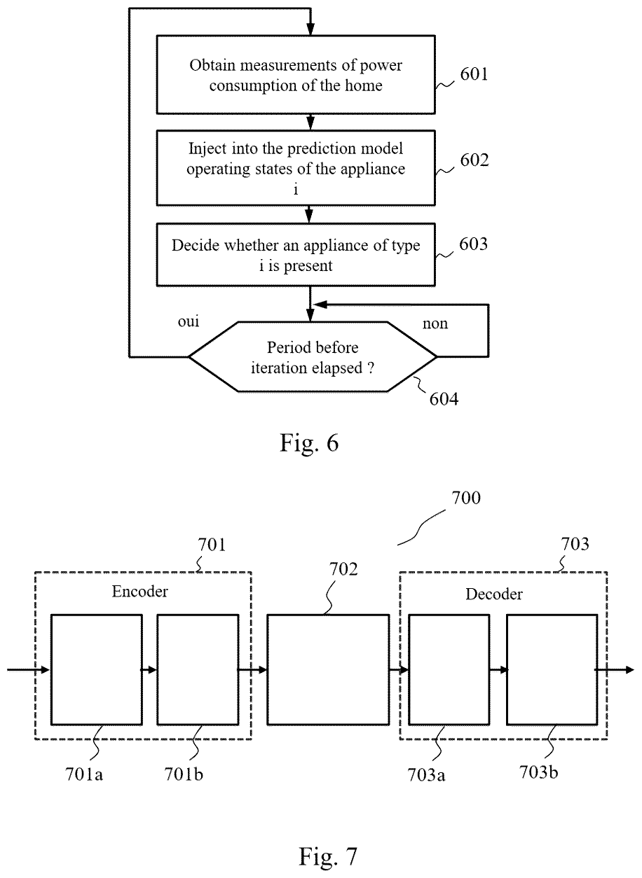

FIG. 6 illustrates schematically an example of an algorithm for iterating the first classification 401-i of each computing branch i appearing in FIG. 4. In summary, the first classification 401-i is repeated periodically, with a predetermined period between two iterations. More precisely, after the performance of the steps 601, 602 and 603, corresponding respectively to the steps 400, 401-i and 402-i of FIG. 4, the processor 101c performs a test step 604 for checking whether a predetermined period before reiteration has elapsed. In the case of negative response at the test step 604, the processor 101c waits and once again performs the test until a positive response is obtained. In the case of positive response at the test step 604, the processor 101c implements a new iteration of the steps 601, 602 and 603, i.e. once again implements the first classification in each of the M computing branches, so that the list of electric appliances detected as present (constituting the first part of the load disaggregation information) can be modified with respect to the previous iteration.

In a particular embodiment, the step 602 of injection of the first measurements into the first machine learning model comprises K iterations, with K>2, of an injection of N′ first measurements into the first machine learning model, configured to provide, according to the N′ first measurements, a first estimated value of an operating state of an electric appliance of the type i. Furthermore, the step 603 of decision relating to the presence of an electric appliance of the type i on the electrical network of the home is dependent on the K first successive estimated values resulting from the K iterations.

FIG. 5 illustrates schematically a second representation of the operational phase of the load disaggregation method, which makes clear and completes the first representation of FIG. 4. In FIG. 5, for each computing branch i, there is detailed the operation referenced 403-i in FIG. 4 and consisting in activating the rest of the computing branch B-i when the decision taken at the step 402-i is that an electric appliance of the type i is present. Thus, if an electric appliance of the type i is detected as present, the processor 101c implements a second classification and then an estimation of individual power consumption.

The second classification comprises:
a step 500 (common to the M computing branches), in which the processor 101c obtains N second measurements of the power consumption of the home, with N>2, provided by the metrology processor 101a during a second interval of time (for example one measurement each second during a time window of N seconds) subsequent to the first interval of time mentioned above (see the step 400 in FIG. 4; and
a step 501-i (specific to the computing branch i), in which the processor 101c injects the N measurements into a second machine learning model of the deep neural network type, configured to provide, according to the N second measurements, an estimated value of an operating state of an electrical appliance of the type i.

The second classification implemented by the processor 101c in each computing branch i improves the quality of the estimation (prediction) of the power consumption of each appliance, made in the step 503-i described below. This is because the load disaggregation solution uses the detection of the events in order to be capable of predicting as close as possible the individual power consumption of each electric appliance.

The second model of the deep neural network type comprises for example a succession of convolutional layers for separating the events observed on the total power consumption of the home.

The second classification phase makes it possible to detect the state “ON” or “OFF” of the electric appliances of type I or the various operating phases of the electric appliances of type II.

When the individual power consumption is estimated (step referenced 503-i in FIG. 5), the processor 101c injects the N measurements of the power consumption of the home (obtained at the step 500), as well as the estimated value of the operating state of the electric appliance of type i (obtained at the step 501-i), into a third machine learning model of the deep neural network type, configured to provide an estimated value of the individual power consumption of the electric appliance of the type i, according to the N measurements and the second estimated value of the operating state of the electrical appliance of the type i.

In a variant illustrated in FIG. 5, for each computing branch i, the processor 101c applies, in a step 502-i, an adaptive filter to the N second measurements of the power consumption of the home, to obtain N second filtered measurements. This adaptive filtering makes it possible to eliminate measurement noises on the electrical network, disturbances on the signal and transient effects. In this variant, it is these N filtered measurements (obtained at the step 502-i) that are injected, with the estimated value of the operating state of the electric appliance of the type i (obtained at the step 501-i), in the third model used at the step 503-i.

FIG. 7 illustrates schematically a particular implementation of the third model used at the step 503-i in FIG. 5. This is a model of the variational autoencoder 700 comprising:
an encoder 701 uses a convolutional layer 701a followed by a first recurrent neural network 701b. The encoder 701 makes it possible to compress and form the latent space of the total power consumption of the home, which is in the form of a random input variable. The convolutional layer 701a makes it possible to elucidate the most important characteristics of the input signal. The recurrent neural network 701b makes it possible to elucidate the time dependencies between the recorded characteristics;
a personalised layer 702 for a stochastic sampling. The purpose thereof is to force the distribution of the latent space in Gaussian. The Gaussian latent variables are the input of the decoder 703. The Gaussian distribution helps the model to more quickly converge towards a solution. This affords better precision at the output of the third model; and
a decoder 703 using a second recurrent neural network 703a followed by a convolutional layer 703b. The decoder 703 decodes, from the latent variables, the individual power consumption of the appliance in question. It uses an architecture that is the inverse of the encoder 701.

The variational autoencoder model makes it possible to generate a random variable (in our case the individual power consumption of the appliance i in question) inferred from another random variable (in our case the total power consumption of the home). It makes it possible to transform this type of problem into a statistical optimisation problem by using the latent space of the input variables. The use of the recurrent neural networks 701b and 703a adds the ability to process the temporal and sequential data such as the periodic consumption of electrical power. In order to optimise the training phase by helping the model to converge quickly, a Gaussian distribution of the latent variables is selected. Improving the convergence affords better training and a more precise result of the estimation of power of each appliance. At the output of the encoder 701, in order to have a Gaussian distribution, a reconfiguration of the latent space of the input variable is done by stochastic sampling. This type of sampling forces the variables to adopt a Gaussian distribution and thus helps the decoder 703 to converge more quickly. The sampling step is modelled by the personalised layer 702. The sizes of the encoder 701 and of the decoder 702 are selected so as to offer less complexity. This choice consists for example in studying the variation in the precision obtained by the load disaggregation model (for each computing branch i) according to the complexity of its architecture, in particular according to the numbers of neurones. The maximum reduction in the number of neurones thus makes it possible to reduce the memory space necessary for implementing the solution. For a few types of electric appliance considered, use is made for example of recurrent networks having approximately 40 neurones, requiring a ROM memory of the order of 0.5 MB.

Although the model proposed above, of a variational autoencoder based on recurrent neural networks, is very efficient, the architecture of the solution proposed can also implement other types of model, which may be different from one computing branch to another.

In the step 504-i of the computing branch i, the processor 101c determines the estimated value of the individual power consumption of the electric appliance of the type i: this is either the one estimated at the step 503-i, if this has been performed, or a zero value if the rest of the branch has not been activated (response “no” at the test 402-i).

After execution (total or partial, depending on the results of the test steps 402-i) of the M computing branches, the processor 101c performs the steps 404 and 405 also present in FIG. 4 and already described above.

Finally, the processor 101c performs a test step 505 to check whether a new measurement of the power consumption of the home has been provided by the metrology processor 101a. In the case of negative response at the test step 505, the processor 101c waits and once again performs the test until a positive response is obtained. In the case of a positive response at the test step 505, the processor 101c implements a new execution of the step 500 (the new set of N measurements comprises the new measurement and the N-1 previous measurements; i.e. use of a sliding window of N measurements with for example one new measurement per second), and then of the steps 402-i, 501-i, 503-i and 504-i of the M computing branches as well as of the steps 404 and 405, so that a new output vector is generated and transmitted (each second in the aforementioned case of a sliding window of N measurements with one new measurement per second).

In order to summarise the operational phase, we present hereinafter an example of use. It is supposed that the solution comprising thirty computing branches (M=30) supporting thirty different types of appliance (one per branch).

During a first period, and after installation of the electricity meter, a step of recording the first measurements of power consumption of the home is provided. The first recording period is for example from a few minutes to a few days and the electricity meter provides, for example each second, a measurement of the power consumption of the home. Once the recording has been done (end of the first period), the first classification for detecting the electric appliances is made. It is supposed that the result of the first classification demonstrates that appliances of sixteen types, out of the thirty types of appliance detectable by the thirty computing branches, are connected to the electrical network of the home.

The fourteen computing branches in which no appliance is detected, i.e. corresponding to unrecognised appliances, are deactivated thereafter. The outputs thereof are equal to zero (zero individual power consumption).

The sixteen other branches are active thereafter. In each active branch, the N last values (samples) read on the meter (N values of power consumption of the home) are given as an input. Suppose that N=10, then the last ten samples form the input of the following two blocks of each branch: the second classification and the adaptive filtering. The second classification provides the operating state of the appliance at the current instant. The same ten values are filtered via the use of the adaptive filter. The part making the estimation of the individual power consumption has as input the operating state of the appliance and the ten filtered values. The updating of the ten values is done for example in the form of a sliding window: the last nine values are kept and the next value that will be read from the electricity meter will be added. The second classification, the filtering and the estimation of the individual power consumption take place almost in precise real time, after the reception of the last sample received by the electricity meter in order to update the sliding window comprising the N values.

### Phase of Adjusting the Coefficients of the Adaptive Filters

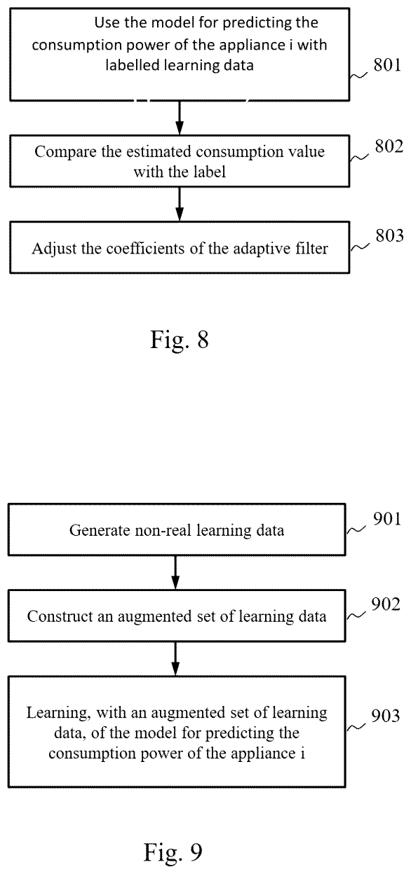

FIG. 8 illustrates schematically a representation of a phase of adjustment of the coefficients of each adaptive filter appearing in FIG. 5. This adjustment phase comprises, for the adaptive filter 502-i of a computing branch i, after the learning phase of the third machine learning model of the computing branch i and before the operational phase using the adaptive filter of the computing branch i:
in a step 801, using the third machine learning model of the computing branch i, with at least one learning data item filtered by the adaptive filter and associated with an output label, to obtain an estimated value of the individual power consumption of the electric appliance of the type i, referred to as the estimated consumption value;
in a step 802, comparing the estimated consumption value with the output label; and
in a step 803, adjusting coefficients of the adaptive filter according to the results of the comparison between the estimated consumption value and the output label.

Adjusting the coefficients of the adaptive filter of the computing branch i makes it possible to reinforce the estimation 503-i of the power consumption of the electric appliance of type i. A set of coefficients is deemed valid if the data generated by the model for estimating the power consumption after filtering of the input signal are more precise than that generated with an unfiltered input signal. These filter coefficients are kept fixed throughout the functional step. An example of a filter that can be selected during the coefficient-fixing step is the averaging filter.

### Learning Phase

Each of the models used in the operational phase (see steps 401-i, 501-i 503-i for each computing branch i) must pass through a training phase. Since these various models concern only one type of appliance per computing branch, the training phase of each model takes into consideration two inputs: the total power consumption of the home and the power consumption of the type of appliance i considered by the branch i.

Some models used in the load disaggregation solution may require large quantities of training data to be precise and effective. Unfortunately, the real data of an electric appliance may not be representative of all the similar electric appliances (i.e. of the same type) that are operating in the whole world. This problem may give rise to a reduction in the quality of the data for training the AI model. In order to solve this problem and to create more universal models from the limited training data available, it is proposed, in a particular embodiment of the invention, to use generative AI models to augment the training data. By using generative AI models, the solution proposed can effectively create instances of synthetic data that closely imitate the characteristics of samples in the real world, which reduces the burden of collecting data.

FIG. 9 illustrates schematically a representation of a learning phase of each model for estimating individual power consumption appearing in FIG. 5. This learning phase comprises, for a learning of the third machine learning model of at least one of the computing branches:
in a step 901, generating non-real learning data with a generative adversarial network model, comprising a generator using a first recurrent neural network and a discriminator using a second recurrent neural network;
in a step 902, constructing an augmented set of learning data, by adding the non-real learning data to the real learning data collected; and
in a step 903, implementing a learning of the third machine learning model with the augmented set of learning data.

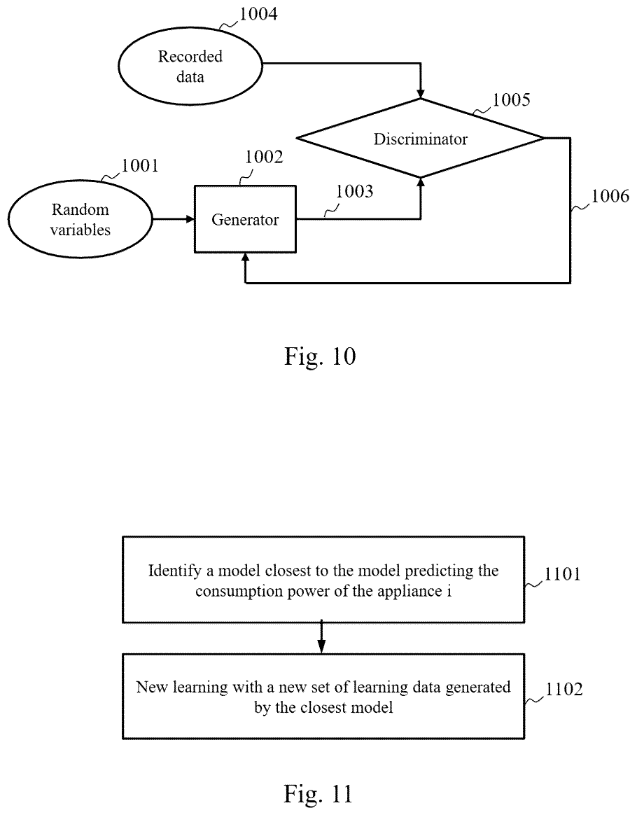

FIG. 10 illustrates schematically a particular implementation of the step 901 of generating non-real learning data, appearing in FIG. 9. Thus a data augmentation solution is proposed that is based on a generative adversarial network model, in which two recurrent neural networks form respectively the generator 1002 and the discriminator 1005. The generator 1002 generates data 1003 from random inputs 1001. The discriminator 1005 judges whether these data 1003 are real or not for the purpose of approaching the appearance of real data 1004 as close as possible. The generator 1002 thus updated (feedback loop 1006) is in a position to generate the augmented data.

In the light of the nature of the use of a few electric appliances, some collected data have much more inactivity states than operating states impacting more zeros on the data. The recorded or augmented data may then be unbalanced, not representing the various operating states equally. In order to remedy this problem, a balancing by synthetic data is used by an oversampling of the minority states. This technique is used during off-line training.

### Phase of Updating the Individual Power-Consumption Estimation Models

FIG. 11 illustrates schematically a representation of a phase of updating each model for estimating individual power consumption appearing in FIG. 5. This updating phase comprises, for updating the third machine learning model of at least one of the computing branches:
in a step 1101, identifying the closest model, from a plurality of reference models, by making a correlation between on the one hand the estimated value provided by the third machine learning model during the operational phase and on the other hand the estimated values provided by the plurality of reference models after injection of data identical to data injected into the third machine learning model during the operational phase; and
in a step 1102, implementing a new learning of the third machine learning model, with a new set of learning data previously generated with the closest model.

This updating phase makes it possible to improve the estimation of the individual power consumption of the type of appliance of the computing branch in question. The third model of each branch for which an appliance has been detected as present on the network of the home can be refined.

1. A load disaggregation method, implemented by a load disaggregation system comprising electronic circuitry, the method comprising an operational phase comprising:
in each computing branch i among M computing branches executed in parallel and each configured for a type i of electric appliance among M types, with M≥2 and 0<i≤M, implementing
a first classification comprising:
obtaining; first measurements of a power consumption of a home, provided during a first interval of time by a smart electricity meter located at the input of an electrical network of the home;
injecting the first measurements into a first machine learning model of the deep neural network type, configured to provide, during the first interval of time, according to the first measurements, first successive estimated values of an operating state of an electrical appliance of the type i; and
deciding, according to the first successive estimated values, whether an electric appliance of the type i is present on the electricity network of the home;
if the first classification results in a decision that an electric appliance of the type i is present on the electricity network of the home;
a second classification comprising:
obtaining N second measurements of the power consumption of the home, provided during a second interval of time, subsequent to the first interval of time, by the smart electricity meter, with N>2;
injecting the N second measurements into a second machine learning model of the deep neural network type, configured to provide, according to the N second measurements, a second estimated value of an operating state of an electrical appliance of the type i;
an estimation, of individual power consumption of the electric appliance of the type i, comprising: injecting the N second measurements of the power consumption of the home and the second estimated value of the operating state of the electric appliance of the type i, into a third machine learning model of the deep neural network type, configured to provide an estimated value of the individual power consumption of the electric appliance of the type i, according to the N second measurements and the second estimated value of the operating state of the electrical appliance of the type i; and
concatenating, in an output vector, M estimated values of individual power consumption associated with the M computing branches, an estimated value of individual power consumption associated with a computing branch i being equal to zero consumption, respectively with the estimated value provided by the third machine learning model of the computing branch i, when the first classification of the computing branch i delivers a decision on absence and respectively a decision on presence of an electric appliance of the type i.

2. The method according to claim 1, wherein:
the injection of the first measurements into the first machine learning model comprises K iterations, with K>2, of an injection of N′ first measurements into the first machine learning model, configured to provide, according to the N′ first measurements, a first estimated value of an operating state of an electric appliance of the type i; and
the decision relating to the presence of an electric appliance of the type i on the electrical network of the home is dependent on the K first successive estimated values resulting from the K iterations.

3. The method according to claim 1, wherein, in each computing branch i, the first classification is repeated periodically, with a predetermined period between two iterations.

4. The method according to one 1, wherein, in each computing branch i, at least two iterations of the second classification, of the estimation, of individual power consumption of the electric appliance of the type i and of the concatenation are implemented, a new iteration being implemented when a new second measurement is provided by the smart electricity meter, the N second measurements obtained during the new iteration comprising the new second measurement and N-1 second measurements that precede the new second measurement.

5. The method according to claim 1, wherein, for at least one of the computing branches, the third machine learning model of the deep neural network type is a variational autoencoder model comprising an encoder using a first recurrent neural network and a decoder using a second recurrent neural network.

6. The method according to claim 1, wherein the operational phase comprises:
transmitting the output vector to at least one item of equipment belonging to a group comprising an item of equipment used by a member of the home and an item of equipment of an electricity supplier supplying the home, with a view to triggering at least one action aimed at acting on a future power consumption of at least one of the electric appliances of the home or on a future total load, planned and managed by the electricity supplier and including a future power consumption of the home.

7. The method according to claim 6, wherein the at least one action belongs to the group comprising:
a display of the operating states and of the individual power consumption of each electric appliance in the home;
a construction of a history of operation of each electric appliance in the home;
a prediction of a future power consumption of the home;
a detection of a deficiency of one of the electric appliances in the home;
a shifting of the future total load, planned and managed by the electricity supplier; and
a partial shedding of the future total load, planned and managed by the electricity supplier.

8. The method according to claim 1, wherein, in each computing branch i, estimating the individual power consumption of the electric appliance of the type i comprises:
applying an adaptive filter to the N second measurements of the power consumption of the home, to obtain N second filtered measurements; and
injecting the N second filtered measurements and the second estimated value of the operating state of the electric appliance of the type i, into the third machine learning model of the deep neural network type, configured to provide the estimated value of the individual power consumption of the electric appliance of the type i, according to the N second filtered measurements and the second estimated value.

9. The method according to claim 8, comprising an adjustment phase comprising, for the adaptive filter of a computing branch i, after a learning phase of the third machine learning model of the computing branch i and before the operational phase using the adaptive filter of the computing branch i:
using the third machine learning model of the computing branch i, with at least one learning data item filtered by the adaptive filter and associated with an output label, to obtain an estimated value of the individual power consumption of the electric appliance of the type i, referred to as the estimated consumption value;
comparing the estimated consumption value with the output label; and
adjusting coefficients of the adaptive filter according to a result of the comparison between the estimated consumption value and the output label.

10. The method according to claim 1, comprising a learning phase comprising, for a learning of the third machine learning model of at least one of the computing branches:
generating non-real learning data with a generative adversarial network model, comprising a generator using a first recurrent neural network and a discriminator using a second recurrent neural network;
constructing an augmented set of learning data, by adding the non-real learning data to real learning data collected; and
implementing a learning of the third machine learning model with the augmented set of learning data.

11. The method according to claim 1, comprising an updating phase comprising, for updating the third machine learning model of at least one of the computing branches:
identifying a closest model, from a plurality of reference models, by making a correlation between on the one hand the estimated value provided by the third machine learning model during the operational phase and on the other hand the estimated values provided by the plurality of reference models after injection of data identical to data injected into the third machine learning model during the operational phase; and
implementing a new learning of the third machine learning model, with a new set of learning data previously generated with the closest model.

12. (canceled)

13. A non-transitory storage medium, storing a computer program product comprising instructions causing the execution, by a processor, of the load disaggregation method according claim 1, when said instructions are read and executed by the processor.

14. The load disaggregation system, comprising electronic circuitry configured to implement the load disaggregation method according to claim 1.

15. A smart electricity meter, comprising a load disaggregation system according to claim 14.
